(19) United States
(12) Patent Application Publication
(10) Pub. No.: US 2016/0278235 A1
(43) Pub. Date: Sep. 22, 2016

(54) HEAT DISSIPATION CASING AND METHOD FOR MAKING THE SAME

(71) Applicant: ADVANCED INTERNATIONAL MULTITECH CO., LTD., Kaohsiung City (TW)

(72) Inventors: Ching-Shan TSAI, Kaohsiung City (TW); Cetera CHEN, Kaohsiung City (TW); Chun-Yu CHANG, Kaohsiung City (TW)

(21) Appl. No.: 14/842,078

(22) Filed: Sep. 1, 2015

(30) Foreign Application Priority Data
Mar. 17, 2015 (TW) 104108471

(51) Int. Cl. H05K 7/20

(52) U.S. Cl. CPC H05K 7/2039

(57) ABSTRACT

A heat dissipation casing is adapted to be mounted to an electronic device, and includes a casing body, a support member and a plurality of thermally conductive fibers. The casing body has an inner surface facing the electronic device, and an outer surface opposite to the inner surface. The support member is connected to the inner surface of the casing body. The thermally conductive fibers are distributed in the support member.

### CROSS-REFERENCE TO RELATED APPLICATION

This application claims priority of Taiwanese Patent Application No. 104108471, filed on Mar. 17, 2015.

### FIELD

The disclosure relates to a heat dissipation casing and a method for making the same.

### BACKGROUND

Heat dissipation has become one of the major concerns for electronic devices. Owing to the large amount of heat generated during operation of high power electronic devices such as cell phones and tablet computers, temperatures thereinmay rapidly increase. Since the cell phones and tablet computers are often placed in a user' s hand or on the user's lap, heat dissipation is particularly important.

### SUMMARY

Therefore, an object of the disclosure is to provide a heat dissipation casing with improved heat dissipation capability, and a method for making the same.

According to a first aspect of the present disclosure, a heat dissipation casing is adapted to be mounted to an electronic device, and includes:

a casing body having an inner surface facing the electronic device, and an outer surface opposite to the inner surface;

a support member connected to the inner surface of the casing body; and

a plurality of thermally conductive fibers distributed in the support member.

According to a second aspect of the present disclosure, a method for making a heat dissipation casing is adapted to be mounted to an electronic device, and includes the following steps:

(a) mixing a plurality of thermally conductive fibers with a fluid matrix;

(b) solidifying the fluid matrix so as to obtain a support member in which the thermally conductive fibers are distributed; and

(c) connecting the support member to an inner surface of a casing body to form the heat dissipation casing, the inner surface being adapted to face the electronic device.

### BRIEF DESCRIPTION OF THE DRAWINGS

Other features and advantages of the present disclosure will become apparent in the following detailed description of the embodiments and variation with reference to the accompanying drawings, of which:

FIG. 1 is a partially exploded side view of a first embodiment of a heat dissipation casing according to the present disclosure and an electronic device;

FIG. 2 is a schematic view of the first embodiment showing a plurality of thermally conductive fibers that are partially exposed from a support member;

FIG. 3 is a partially exploded side view of a second embodiment of the heat dissipation casing and an electronic device;

FIG. 4 shows a variation of the second embodiment;

FIG. 5 is a flow chart of a method for making the heat dissipation casing according to the present disclosure;

FIG. 6 is a perspective view showing that the thermally conductive fibers are aligned along two long lateral sides of the support member and are exposed from a casing body; and

FIG. 7 is a schematic view showing connection of the support member and the casing body using a molding technique.

### DETAILED DESCRIPTION

Before the disclosure is described in further detail with reference to the accompanying embodiments and variation, it should be noted herein that like elements are denoted by the same reference numerals throughout the disclosure.

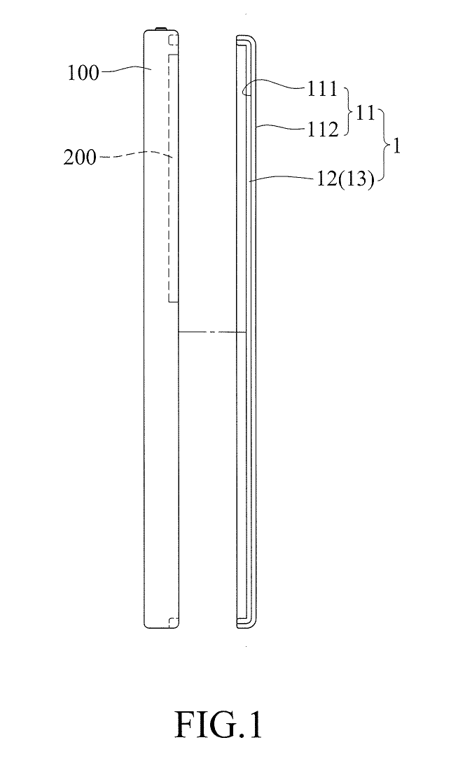

Referring to FIG. 1, a first embodiment of a heat dissipation casing 1 according to the present disclosure is adapted to be mounted to an electronic device 100 including a high power element 200. The heat dissipation casing 1 dissipates heat generated by the high power element 200. The electronic device 100 may be a cell phone, a tablet computer, etc. In this embodiment, the electronic device 100 is a cell phone. In practical use, the heat dissipation casing 1 replaces a cover of the electronic device 100 for dissipating heat generated by the high power element 200 of the electronic device 100.

The heat dissipation casing 1 includes a casing body 11, a support member 12 and a plurality of thermally conductive fibers 13. The casing body 11 has an inner surface ill facing the electronic device 100, and an outer surface 112 opposite to the inner surface 111. The support member 12 is connected to the inner surface 111 of the casing body 11. The thermally conductive fibers 13 are distributed in the support member 12.

The casing body 11 may be made of a metal-based material or a polymer material, such as a titanium alloy, an aluminum alloy, polycarbonate,polymethylmethacrylate, etc.

The support member 12 maybe flexible and may be made of a polymer material or a metal-based material. Specifically, the polymer material maybe an epoxy resin, a phenol formaldehyde resin, a furan resin or a polyurethane resin. The metal-based material may be silver, copper, tin, antimony, aluminum, an aluminum magnesium alloy or an aluminum alloy. Since the support member 12 is made to be flexible, the support member 12 can be fittingly connected to the casing body 11 so as to improve the heat dissipation efficiency.

Alternatively, the support member 12 may be made of a ceramic material, e.g., silicon and silicon carbide. The support member 12 is configured to have a shape conforming with that of the casing body 11 during solidification (see infra).

The thermally conductive fibers 13 have a thermal conductivity ranging from 380 W/m·K to 2000 W/m·K, and may be metal fibers, carbon fibers, or the combination thereof. Specifically, the carbon fibers are high thermal conductivity carbon fibers, e.g., graphitized vapor grown carbon fibers.

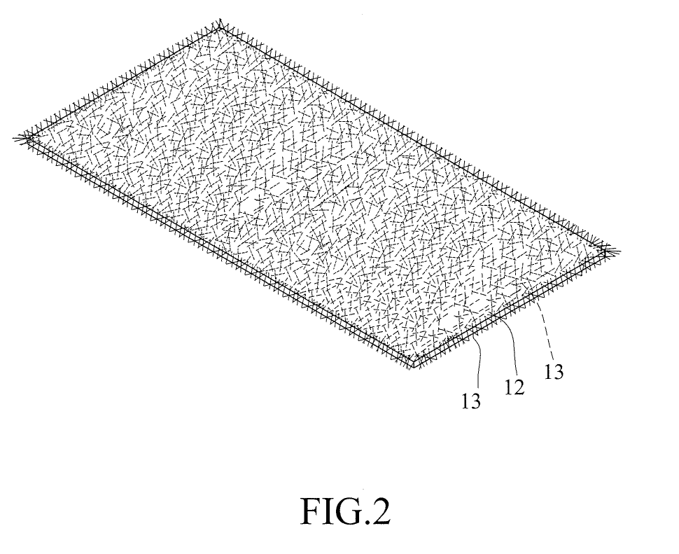

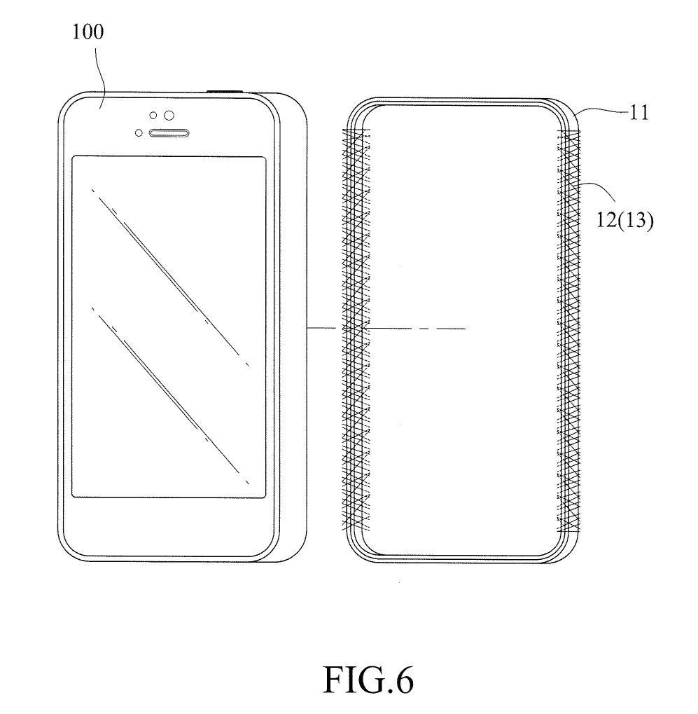

Referring further to FIG. 2, in this embodiment, the thermally conductive fibers 13 are partially exposed from the support member 12, thereby increasing heat dissipation capability of the heat dissipation casing 1. In one example, the thermally conductive fibers 13 are partially exposed from four lateral sides (including two long lateral sides and two short lateral sides) of the support member 12. In another example, the thermally conductive fibers 13 are aligned along and partially exposed from the two long lateral sides of the support member 12 (see FIG. 6). The thermally conductive fibers 13 may be further exposed from the casing body 11 to further improve heat dissipation efficiency (see FIG. 6).

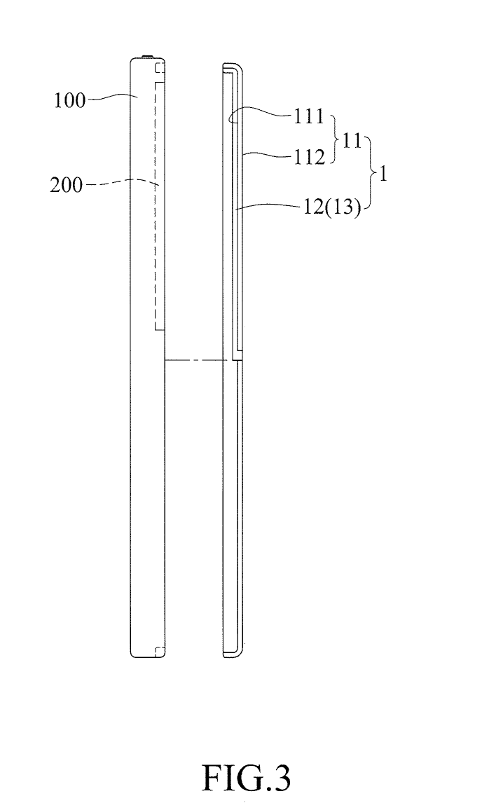

Referring to FIG. 3, a second embodiment of the dissipation casing 1 according to the present disclosure has a structure similar to that of the first embodiment. The differences reside in that the support member 12 is formed on a portion of the inner surface 111 of the casing body 11 and a part of the support member 12 extends through the casing body 11 to be exposed from the outer surface 112 of the casing body 11.

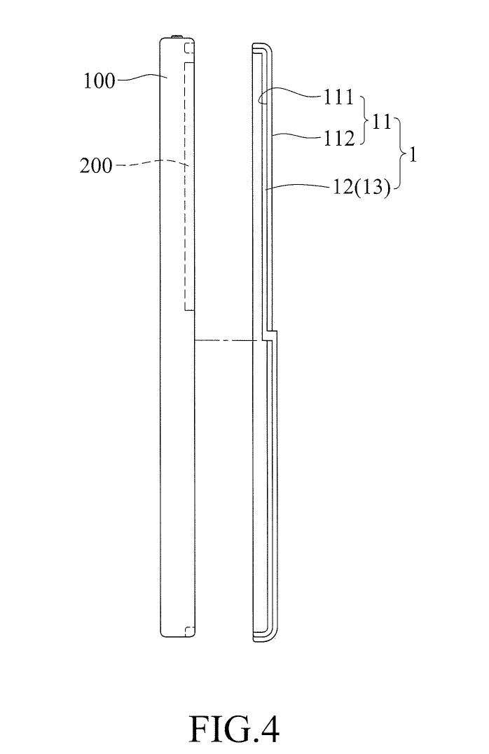

FIG. 4 is a variation of the second embodiment of the dissipation casing 1, in which the part of the support member 12 extends through the casing body 11 and onto the outer surface 112 of the casing body 11, thereby increasing the area of the heat dissipation casing 1 that contacts the external environment so as to increase heat dissipation efficiency.

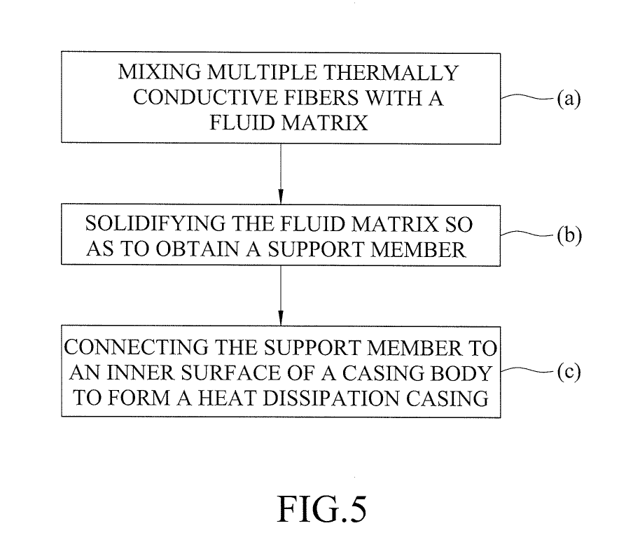

Referring to FIGS. 5 and 6, a method for making the first embodiment of the heat dissipation casing 1 according to the present disclosure includes the following steps:

(a) mixing the thermally conductive fibers 13 with a fluid matrix;

(b) solidifying the fluid matrix so as to obtain the support member 12 in which the thermally conductive fibers 13 are distributed; and

(c) connecting the support member 12 to the inner surface 111 of the casing body 11 to form the heat dissipation casing 1.

In step (a), when the support member 12 is made of polymer or metal, the polymer or metal is melted into the fluid matrix before mixing the thermally conductive fibers 13 therewith. When the support member 12 is made of ceramic, the fluid matrix is prepared by adding ceramic powders (e.g., Si powders, SiC powders, etc.) into a dispersing agent (e.g., polyethyleneimine/isopropyl alcohol), performing ultrasonic vibration to evenly distribute the ceramic powders in the dispersing agent so as to obtain a dispersion, and adding the dispersion into a resin material (e.g., phenol formaldehyde resin).
In step (b), the fluid matrix is solidified into the support member 12 to have a shape conforming with that of the inner surface 111 of the casing body 11. In the first embodiment, the casing body 11 is rectangular in shape and therefore the support member 12 is made to have a substantially rectangular shape. However, the shape of the support member 12 does not need to conform with that of the casing body 11 and may be configured according to practical requirements. For example, the support member 12 may be configured to have a shape conforming with that of the high power element 200, e.g., a trapezoidal shape, a polygonal shape, etc. When the support member 12 is made of polymer or metal, the fluid matrix is directly solidified into the support member 12. When the support member 12 is made of ceramic, the fluid matrix (in slurry form) mixed with the thermally conductive fibers 13 is hot-pressed at a temperature ranging from 150° C. to 170° C. into a flexible member that can be configured to a shape (e.g., an L shape in FIG. 2 or a Z shape in FIG. 3) conforming with that of the inner surface 111 of the casing body 11. Then, the flexible member is heated to 1100° C. to pyrolyze and carbonize the resin material in the fluid matrix and is further treated at 1450° C. for 3 hours to obtain the support member 12 made of ceramic.

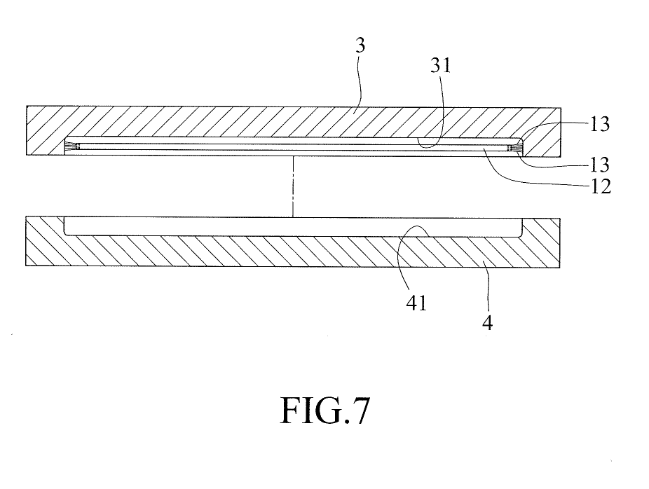

Referring particularly to FIG. 6, in step (c), the support member 12 is connected to the inner surface 111 of the casing body 11 using, e.g., an adhesive or a molding technique. As shown in FIG. 7, when the molding technique is used, step (c) includes the following sub-steps:

(c1) providing a first mold 3 that defines a first cavity 31, and a second mold 4 that corresponds in position to the first mold 3 and that defines a second cavity 41 having a shape corresponding to that of the casing body 11;

(c2) placing the support member 12 with the thermally conductive fibers 13 in the first cavity 31 of the first mold 3;

(c3) injecting a molten material into the second cavity 41 of the second mold 4;

(c4) solidifying the molten material to form the casing body 11 and to connect the support member 12 to the casing body 11; and

(c5) removing the first and second molds 3, 4.

Note that the configuration of the first and second molds 3, 4 should be adjusted according to the shape of the casing body 11 and the support member 12 in order to obtain the heat dissipation casing with different configurations, e.g., as shown in the first embodiment, second embodiment and the variation of the second embodiment.

The method may further include, before step (c), a step (d) of removing apart of the support member 12 such that the thermally conductive fibers 13 are partially exposed from the support member 12. In step (c), the part of the support member 12 may be removed by laser, sandblasting or chemical erosion. Specifically, the chemical erosion method is used when the support member 12 is made of metal. It should be noted that step (d) may be omitted depending on actual requirements (e.g., operating environment or demand for dissipation efficiency).

To sum up, the present disclosure provides a heat dissipation casing 1 including the support member 12 and the thermally conductive fibers distributed in the support member 12. The support member 12 may be flexible so as to fittingly connect to the inner surface 111 of the casing 11. The thermally conductive fibers 13 may be configured to be exposed from the support member 12 to improve heat dissipation efficiency.

While the disclosure has been described in connection with what are considered the exemplary embodiments and variation, it is understood that this disclosure is not limited to the disclosed embodiments and variation but is intended to cover various arrangements included within the spirit and scope of the broadest interpretation so as to encompass all such modifications and equivalent arrangements.

What is claimed is:

1. A heat dissipation casing adapted to be mounted to an electronic device, comprising:
a casing body having an inner surface facing the electronic device, and an outer surface opposite to said inner surface;
a support member connected to said inner surface of said casing body; and
a plurality of thermally conductive fibers distributed in said support member.

2. The heat dissipation casing as claimed in claim 1, wherein said thermally conductive fibers are partially exposed from said support member.

3. The heat dissipation casing as claimed in claim 1, wherein a part of said support member extends through said casing body and is exposed from said outer surface of said casing body.

4. The heat dissipation casing as claimed in claim 1, wherein said thermally conductive fibers are selected from the group consisting of metal fiber, carbon fiber and the combination thereof.

5. The heat dissipation casing as claimed in claim 1, wherein said support member is flexible.

6. The heat dissipation housing as claimed in claim 5, wherein said support member is made of a material selected from the group consisting of polymer and metal.

7. The heat dissipation casing as claimed in claim 1, wherein said support member is made of ceramic.

8. A method for making a heat dissipation casing adapted to be mounted to an electronic device, the method comprising the following steps:
(a) mixing a plurality of thermally conductive fibers with a fluid matrix;
(b) solidifying the fluid matrix so as to obtain a support member in which the thermally conductive fibers are distributed; and
(c) connecting the support member to an inner surface of a casing body to form the heat dissipation casing, the inner surface being adapted to face the electronic device.

9. The method of claim 8, wherein the thermally conductive fibers have a thermal conductivity ranging from 380 W/m·K to 2000 W/m·K.

10. The method of claim 9 further comprising, before step (c), step (d): removing a part of the support member such that the thermally conductive fibers are partially exposed from the support member.

11. The method of claim 10, wherein step (d) is performed using laser, sandblasting or chemical erosion.

12. The method of claim 8, wherein, in step (c), the support member is connected to the casing body using an adhesive.

13. The method of claim 8, wherein step (c) includes the following sub-steps:
(c1) providing a first mold that defines a first cavity, and a second mold that corresponds in position to the first mold and that defines a second cavity having a shape corresponding to that of the casing;
(c2) placing the support member with the thermally conductive fibers in the first cavity of the first mold;
(c3) injecting a molten material into the second cavity of the second mold;
(c4) solidifying the molten material to form the casing body and to connect the support member to the casing body; and
(c5) removing the first and second molds.

14. The method of claim 13, wherein the casing body has an outer surface opposite to the inner surface, a part of the support member extending through the casing body and being exposed from the outer surface of the casing body.

15. method of claim 14, wherein the part of the support member extends onto the outer surface of the casing body.

16. The method of claim 8, wherein the support member is flexible.

17. The method of claim 16, wherein the support member is made of a material selected from the group consisting of polymer and metal.

18. The method of claim 17, wherein the polymer is selected from the group consisting of an epoxy resin, a phenol formaldehyde resin, a furan resin and a polyurethane resin.

19. The method of claim 8, wherein the support member is made of ceramic.

20. The method of claim 8, wherein the thermally conductive fibers are selected from the group consisting of metal fiber, carbon fiber and the combination thereof.
